(19) United States
(12) Patent Application Publication
(10) Pub. No.: US 2026/0324423 A1
(43) Pub. Date: Oct. 15, 2026

(54) MOLDED SEMICONDUCTOR DEVICE PACKAGE WITH A MICROCHANNEL COMPONENT

(71) Applicant: SEMICONDUCTOR COMPONENTS INDUSTRIES, LLC, Scottsdale, AZ (US)

(72) Inventors: Seokbong KIM, Paju-si (KR); Byoungok LEE, Yeonsu-gu (KR); Yong LIU, Cumberland Foreside, ME (US)

(73) Assignee: SEMICONDUCTOR COMPONENTS INDUSTRIES, LLC, Scottsdale, AZ (US)

(21) Appl. No.: 19/174,058

(22) Filed: Apr. 9, 2025

(51) Int. Cl. H10W 40/40; H10W 40/60; H10W 74/01; H10W 74/10

(52) U.S. Cl. CPC H10W 40/40; H10W 40/611; H10W 74/01; H10W 74/111

(57) ABSTRACT

A package includes a mold body encapsulating at least a semiconductor die. A microchannel component is embedded in a surface of the mold body with a manifold area being exposed on the surface of the mold body. The manifold area has openings of microchannels that extend from the manifold area through a thickness of the microchannel component.

### TECHNICAL FIELD

This description relates to assembling and packaging semiconductor device modules, semiconductor device assemblies, and semiconductor devices. More specifically, this description relates to cooling of semiconductor device module packages.

### BACKGROUND

Semiconductor device assemblies (e.g., chip assemblies), which include power semiconductor devices can be implemented using semiconductor dies, substrates (e.g., die attach pads (DAPs)), electrical interconnections, and a molding compound. Power transistors can include, for example, insulated-gate bipolar transistors (IGBTs), power metal-oxide-semiconductor field effect transistors (MOSFETs), bridge rectifiers, and so forth. To safeguard the semiconductor devices or components against mechanical damage, contamination, and moisture, the semiconductor device components can be packaged in an encapsulant. An electronic molding compound (EMC) may, for example, serve as an encapsulant to protect the semiconductor device component in a package. Further, it is important to keep a semiconductor device component’s junction temperature below a maximum allowed temperature. In example implementations, heat flow from the semiconductor device component through the package to the ambience can be managed by integrating a heat dissipator (e.g., a base plate, a heat sink, etc.) within, or attached to, the package.

### SUMMARY

In a general aspect, a package includes a mold body made of an epoxy material. The mold body may have a three-dimensional rectangle shape. The mold body encapsulates at least a semiconductor die. A microchannel component is embedded in a surface of the mold body with a manifold area being exposed on the surface of the mold body. The manifold area has openings to microchannels that extend from the manifold area through a thickness of the microchannel component.

In a general aspect, a package includes a mold body. The mold body is made of epoxy material and encapsulates a stack. The stack includes a microchannel component having a surface with a manifold area. The manifold area includes openings to a plurality of microchannels that extend from the manifold area through a thickness of the microchannel component. An insulating component is bonded to the microchannel component on a side of the microchannel component opposite the surface with the manifold area. Further, a metal layer is disposed on the insulating component, and at least one semiconductor device die is disposed on the metal layer.

In a general aspect, a method includes bonding an insulating component to a top surface of a microchannel component. The bottom surface of the microchannel component has a manifold area including openings to a plurality of microchannels that extend from the manifold area through a thickness of the microchannel component. In other words, one or more of the plurality of microchannels extends through a thickness of the microchannel component. The method further includes bonding a metal layer to the insulating component, disposing at least one semiconductor device die on the metal layer, and encapsulating a stack including the at least one semiconductor device die, the metal layer, the insulating component and the microchannel component in an epoxy forming a mold body of a semiconductor device package. Encapsulating the stack includes encapsulating the stack such that the manifold area on the bottom surface of the microchannel component remains exposed outside of the semiconductor device package.

The foregoing illustrative summary, as well as other objectives and/or advantages of the disclosure, and the manner in which the same are accomplished, are further explained in the following detailed description, and accompanying drawings.

### BRIEF DESCRIPTION OF THE DRAWINGS

FIG. 1A illustrates a cross-sectional view of an example microchannel component configured to cool a semiconductor die.

FIG. 1B illustrates an example microchannel component attached to a surface of a mold body of a semiconductor components package.

FIG. 2 illustrates, in a perspective view, an example microchannel component.

FIG. 3 illustrates a side surface portion of an example microchannel component with an example mold-lock component.

FIG. 4 illustrates a side surface portion of an example microchannel component with another example mold-lock component.

FIG. 5 illustrates a side surface portion of an example microchannel component with yet an example mold-lock component.

FIG. 6 illustrates a side surface portion of an example microchannel component with still another example mold-lock component.

FIG. 7 illustrates an adhesive layer disposed on a side surface of a microchannel component.

FIG. 8 illustrates, in a cross-sectional view, an example assembly of a microchannel component that is physically or mechanically integrated with a device stack in a semiconductor device package.

FIG. 9 illustrates, in a perspective view (like FIG. 2), an example microchannel component attached to an insulating component.

FIG. 10 illustrates, in a plan view, a metal layer that is patterned to include multiple pads that are isolated from each other.

FIG. 11A illustrates a device stack with four holes at the four corners at top of the device stack.

FIG. 11B illustrates a device stack with four holes at the four corners at a bottom of the device stack.

FIG. 12 illustrates an example method of using a microchannel component to dissipate heat generated in a semiconductor device package.

FIG. 13 illustrates an example method of using a microchannel component to dissipate heat from a semiconductor device package.

Aspects of the present disclosure are best understood from the following detailed description when read in conjunction with the accompanying figures. It is noted that, in accordance with general practice in the field, various features are not necessarily drawn to scale. Dimensions of the various features may be arbitrarily increased or reduced for clarity in visualization and discussion. The drawings illustrate generally, by way of example, but not by way of limitation, various implementations discussed in the present disclosure. In the various drawings, like reference symbols may indicate like and/or similar components (elements, structures, etc.) in different views. Reference symbols or numerals shown in one drawing may not be repeated for the same, and/or similar elements in related views. Reference symbols or numerals that are repeated in multiple drawings may not be individually discussed with respect to each of those drawings but are provided for context between related views. Also, not all elements in the drawings may be specifically identified with a reference symbol or numeral when multiple instances of an element are illustrated.

### DETAILED DESCRIPTION

Semiconductor packaging is a crucial aspect of electronics manufacturing that involves enclosing semiconductor chips and circuits in protective and functional packages to ensure their reliability, performance and integration into electronic systems. These packages serve as a bridge between the tiny, sensitive semiconductor chips and the broader electronic systems, providing electrical connections, thermal management, and environmental protection.

Molding is the process of packaging (encapsulating) the device circuit or module in a hard plastic material (e.g., an electronic molding compound (EMC) such as an epoxy resin). Transfer or injection molding is a widely used molding process in the semiconductor industry. In this process, the device circuits and substrates to be encapsulated are placed in mold cavities in a mold form or chase. A molding compound in a fluid state (molten) is forced by a hydraulic plunger into the runners of the mold chase. These runners serve as canals through which the fluid molding compound travels until it reaches the mold cavities, which contain the device circuit or module and substrates to be encapsulated. The mold form or chase may include a top mold cavity block and a bottom mold cavity block, which respectively define an upper surface and a lower surface of the mold cavity that is filled with the fluid molding compound to encapsulate the object (e.g., the device circuit or module) placed in the mold cavity.

A semiconductor device package may include one or more semiconductor devices (chips or dies) encapsulated in a mold body made of a plastic or epoxy material. The plastic or epoxy material can, for example, be a cresol-novolak epoxy resin, a siloxane polyimide, a polyxylylene, a silicone, a polyepoxide or a bisbenzocyclo-butene. The semiconductor device package may include a single chip or include multiple chips with different functionalities (e.g., processors, memory, and sensors) encapsulated in a mold body. External terminals extending from the mold body may provide pathways for sending or receiving input/output signals from the encapsulated chips in the mold body. These external terminals may be shaped, for example, to allow the semiconductor device package to be surface mounted (e.g., on a printed circuit board). The external terminals may, for example, be press-fit in holes in the printed circuit board, or soldered to traces on the printed circuit board to surface mount the package.

Microchannel component (e.g., a microchannel cooler (MCC)) are thermal management solutions designed to efficiently dissipate heat in high-performance electronics. These cooling systems are particularly crucial in applications such as laser diodes, power electronics, and high-performance computing, etc., where managing excessive heat is critical for maintaining optimal performance and longevity. The microchannel components can be used to cool an individual semiconductor die or to cool a group of semiconductor dies in an electronic circuit package.

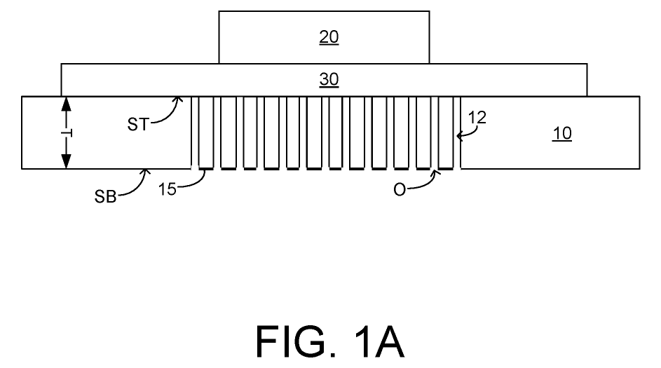

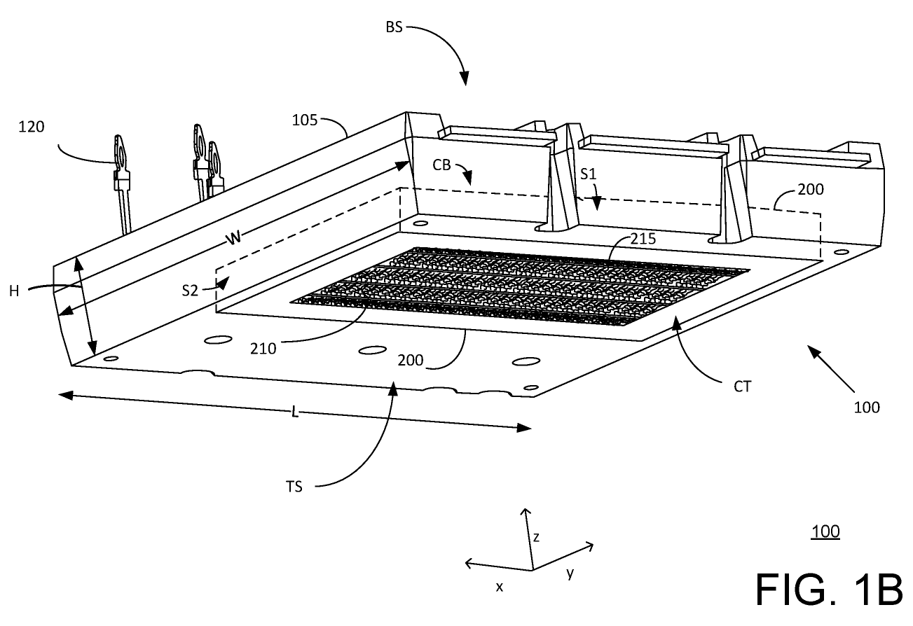

FIG. 1A shows a cross-sectional view of a microchannel component 10 deployed to cool a semiconductor die 20. Semiconductor die 20 may be disposed on a substrate 30 (e.g., a printed circuit board, a direct bonded metal (DBM) substrate). Microchannel component 10 may have the shape of a rectangular prism having, for example, a top surface ST, a bottom surface SB, and a thickness T. The top surface ST of microchannel component 10 may be attached to substrate 30 on which the semiconductor die 20 is disposed. The bottom surface (e.g., surface SB) of microchannel component has a manifold area 15 with openings (e.g., opening O) to microchannels (e.g., microchannel 12) that extend from manifold area 15 to the top surface ST of microchannel component 10 across the thickness T of microchannel component 10. Heat generated by semiconductor die 20 may be dissipated to an ambient environment through the openings (e.g., opening O) by a fluid (e.g., air) included within and/or circulating in the microchannels (e.g., microchannel 12).

In example implementations, removal of heat generated by the semiconductor devices in a package may be accomplished by a microchannel component attached to, or embedded in, an outer surface of the mold body of the package.

The microchannel component may include a manifold area having openings to microchannels extending through the microchannel component from one side of the microchannel component to an opposite second side of the microchannel component. The microchannels may have vents or openings at a surface of the microchannel component in the manifold area such that air can flow from one side of the microchannel component to the opposite side of the microchannel component through the microchannels. Air flow through the microchannels from (e.g., extending from) one side of the microchannel component to the opposite side of the microchannel component may carry and dissipate heat generated in the package to outside of the package. The manifold area can include openings to a plurality of microchannels that extend through a thickness of the microchannel component to a back surface in thermal contact with the semiconductor die (and/or DBM).

In example implementations, a semiconductor device package (e.g., a Schottky barrier rectifier diode package) with microchannel cooling may include the following stack of items: a microchannel component, an insulating component, a top copper patterned layer with a top copper pattern, a die adhesive, and a semiconductor die, etc., encapsulated in a mold body.

FIG. 1B shows an example semiconductor device package 100 having a microchannel component 200 attached to a surface of a mold body 105 of the package for thermal management. As shown in FIG. 1B, mold body 105 of semiconductor device package 100 may have a generally rectangular box or tub-like shape with, for example, a length L, a width W and a height H. The rectangular box or tub-like shape may have a top surface TS and a bottom surface BS. Mold body 105 of semiconductor device package 100 may be made of an epoxy resin (e.g., an EMC) or other plastic materials and may encapsulate a single semiconductor die or multiple semiconductor die (not visible because they are encapsulated in the mold body 105).

In example implementations, external terminals (e.g., terminals 120 and/or at least a portion of a leadframe) may extend from and/or be coupled to the semiconductor dies and may have at least a portion exposed outside of the mold body 105. Terminals 120 may, for example, be wire-like or rod-like structures with compressible tips and may extend out from a bottom surface BS of mold body 105. In example implementations, the compressible tips may have needle eye-like structures.

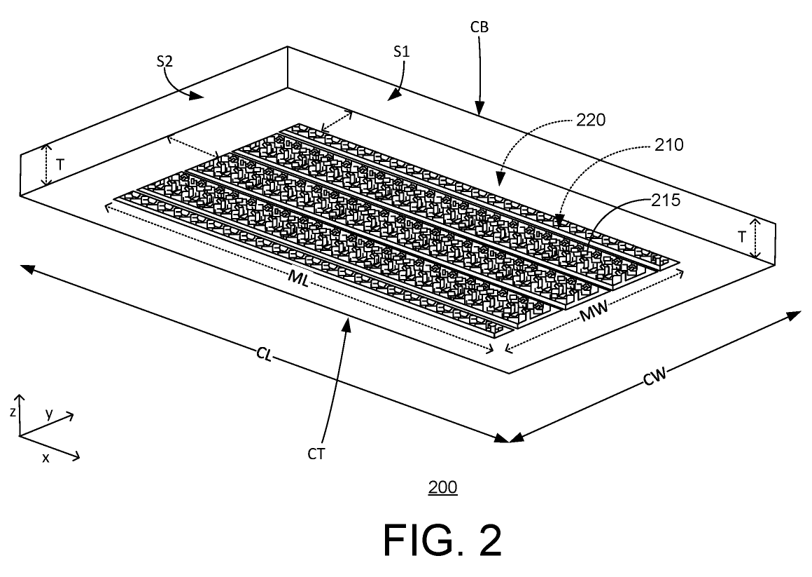

Further, as shown in FIG. 1B, a microchannel component (e.g., microchannel component 200, FIG. 2) may be embedded (or buried) in top surface TS of mold body 105 of semiconductor device package 100. A manifold area 210 of microchannel component 200 may be exposed on a top surface TS of mold body 105. Manifold area 210 may include openings or vents (e.g., holes 215) of microchannels that extend through a thickness T of the microchannel component 200. Fluid flow (e.g., air flow) through the microchannels from one side of the to the opposite side of the can carry and dissipate heat generated in the package to outside of the package. The manifold area 210 can include openings to a plurality of microchannels that extend through a thickness of the microchannel component 200 to a back surface (e.g., bottom side CB) in thermal contact with a semiconductor die (not shown) disposed within the mold body 105.

In the example shown in FIG. 1B, microchannel component 200 may be at least partially buried (or may be fully encapsulated within (e.g., buried)) in mold body 105 (except for the manifold area 210), which makes up mold body 105 in semiconductor device package 100. The mold body 105 may cover and adhere to (or bond to) the back surface (e.g., bottom side CB) and most of the sides (e.g., side S1 and side S2) of microchannel component 200 to hold microchannel component 200 in place within mold body 105. As partially encapsulated in the mold body 105, the top surface (e.g., top side CT) of microchannel component 200 including manifold area 210 may not be covered by mold body 105 and may be exposed to an ambient environment (e.g., outside of the package). In some example implementations, a top surface CT of microchannel component 200 (including manifold area 210) may be flush with (or level with) the top surface TS of a package. In some example implementations, microchannel component 200 may be placed in a recess (not shown) in mold body 105 such that top surface CT of microchannel component 200 is below the top surface TS of the package. In such instances at least a portion of the side S1 and/or the side S2 may be exposed outside of the mold body 105. Although only two sides S1 and side S2 are shown, the microchannel component 200 can have at least four sides in some implementations.

In some implementations, a thickness of the microchannel component 200 may be less than a thickness of the mold body 105. In other words, a thickness of the side S1 and/or side S2 can be less than a thickness of a side of the mold body 105. In some implementations, the side S1 and/or the side S2 may be fully enclosed within the mold body 105. In other words, the side S1 and/or the side S2 may not be exposed outside of the mold body 105.

In some implementations, a molding compound (e.g., molding material or compound, an encapsulation material) that can be included in the mold body 105 can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a module (e.g., a package including a semiconductor device) can be included in another module. The module can be referred to as a package. For example, one or more modules can be one or more sub modules included within another module. In other words, a first module can be included as a sub module within a second module.

FIG. 2 shows a perspective view of an example microchannel component 200. microchannel component 200 may be made of a metal (e.g., copper), a metal alloy, or a composite material. Microchannel component 200 may have any shape (e.g., a rectangular shape, a circular shape, an oval shape, etc.). In example implementations, microchannel component 200, as shown in FIGS. 1B and 2, may have a rectangular shape, for example, with a length CL, a width CW.

Microchannel component 200 may have a top side CT, and a bottom side CB. Microchannel component 200 may have a thickness T between top side CT and bottom side CB. Microchannel component 200 may have rectangle sides (e.g., sides S1 and S2) extending between top side CT and bottom side CB. Top side CT may include a manifold area (e.g., manifold area 210) that includes openings and vents (e.g., hole 215) of microchannels (not visible) extending from one side of the to an opposing second side of the. In example implementations, manifold area 210 may have a rectangular, an oval, a circular, or other arbitrary shape. In the example shown in FIG. 2, manifold area 210 may have a rectangular shape with a length ML and a width MW. Manifold area 210 may be positioned in a central portion of top side CT such that a rectangular frame portion 220 of microchannel component 200 surrounds manifold area 210. Rectangular frame portion 220 may be free of microchannels, free of openings or vents to the microchannels, and may have a smooth surface on top side CT of microchannel component 200.

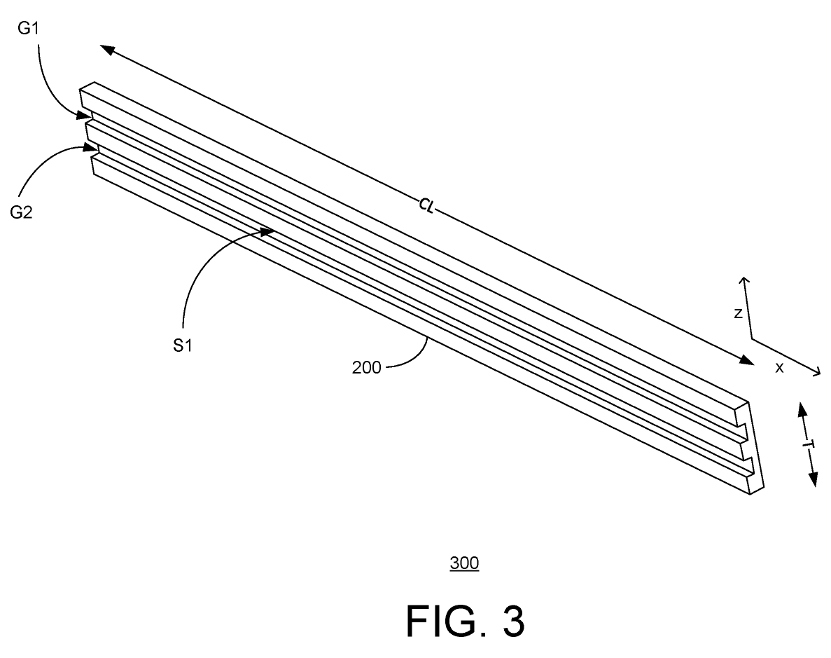

Similarly, in an example implementation, the sides (e.g., side S1 and side S2) of microchannel component 200 may be smooth surfaces. In some implementations, one or more of the sides S1 and/or side S2 of microchannel component 200 may not be a smooth surface and may include one or more mold-lock components, which are described in connection with FIGS. 3-6.

Some instances relying on mold body 105 to adhere (or bond) to smooth sides (e.g., side S1 and S2) to hold microchannel component 200 in place in mold body 105 may present a delamination risk (e.g., after thermal cycling). The smooth surfaces of microchannel component 200 may encourage or allow slippage of the microchannel component 200 out of the mold body 105 of semiconductor device package 100.

In accordance with the principles of the present disclosure, a mold-lock component is disposed on a surface of a microchannel component 200. In some implementations, one or more mold-lock components can be formed within a surface of a microchannel component 200. The mold-lock component may, for example, include grooves, protrusions, friction holes, and/or so forth. The mold-lock components (e.g., mold-lock components) disposed on the surfaces of microchannel component 200 may provide mold body 105 a better or a stronger grip on microchannel component 200 and reduce slippage and delamination in mold body 105.

FIGS. 3-6 show only a side surface portion (e.g., side S1) of microchannel component 200 shown and described in connection with any of the figures herein. Various example mold-lock components are shown in FIGS. 3-6 as being disposed on side S1 of microchannel component 200 shown and described in connection with any of the figures herein. One of more of the structures illustrated in FIGS. 3-6 can be formed in or from one or more sides of the microchannel component 200 shown and described in connection with any of the figures herein. Any combination or portion of the structures illustrated in FIGS. 3-6 can be formed in or from one or more sides of the microchannel component 200 shown and described in connection with any of the figures herein. In some implementations, for example, a portion of one or more of the structures can be formed on a portion (on a portion of a thickness and/or on a portion of a length) of a side of the microchannel component 200 shown and described in connection with any of the figures herein. Although many of the implementations described in connection with FIGS. 3-6 are discussed in connection with side S1, the features can be associated with any side of a microchannel component 200 shown and described in connection with any of the figures herein.

In example implementations, the mold-lock component disposed on the surface of the microchannel component includes at least one groove (also can be referred to as a channel or as a lateral channel) disposed along a length (or a portion of a length) of a surface of microchannel component 200 as a surface roughening feature. FIG. 3, for example, shows a side surface 300 (e.g., side S1 in the x-z plane) with two grooves (e.g., groove G1 and groove G2) formed in or on side S1. Side S1 of microchannel component 200 may be a rectangular strip with a long length CL along an edge of the microchannel component 200, and a short length equal to the thickness T of the and perpendicular to the long length CL. The two grooves (e.g., groove G1 and groove G2) may be linear or longitudinal grooves that extend linearly along the long length (length CL) of side S1 in the x direction. More or less grooves can be included in the implementation shown in at least FIG. 3.

In some implementations, the grooves (e.g., groove G1, G2) may be grooves that extend over less than the thickness T of microchannel component 200 in the x direction perpendicular to the long length (length CL) of side S1. In some implementations, the n grooves (e.g., groove G1, G2) may be grooves that extend over only a portion of the thickness T of microchannel component 200 in the z direction perpendicular to the long length (length CL) of side S1. In some implementations, the grooves (e.g., grooves G1, G2) may be non-linear grooves that extend over at least a portion of the thickness T of microchannel component 200 in the x direction perpendicular to the long length (length CL) of side S1.

In some implementations, the grooves shown in FIG. 3 may be irregularly spaced. In some implementations, the grooves shown in FIG. 3 may be irregularly shaped.

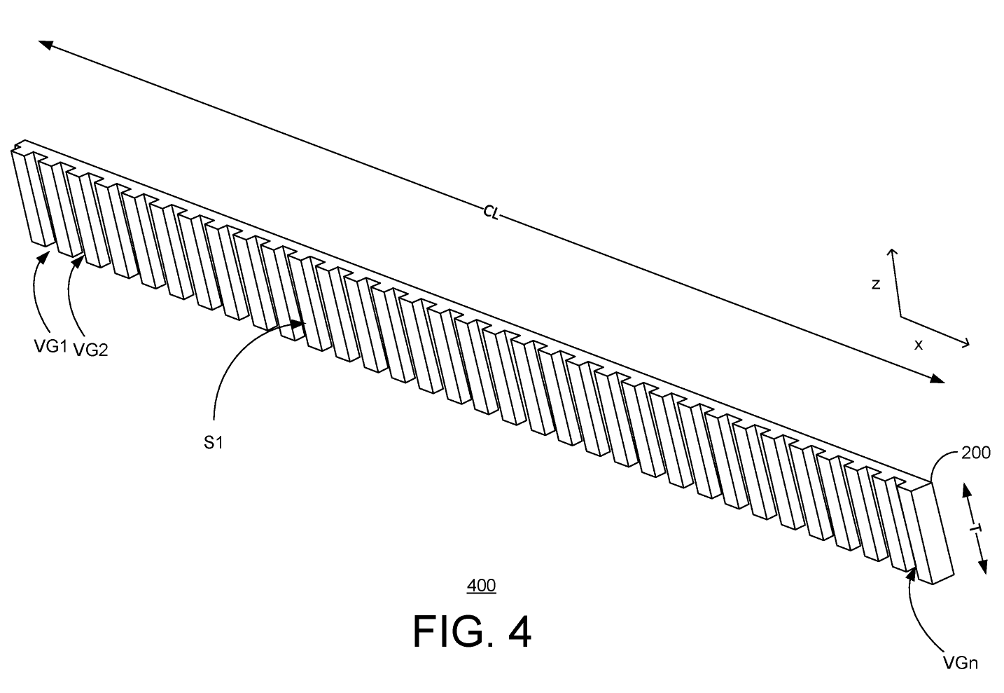

In other example implementations, the mold-lock component disposed on the surface of the microchannel component may include a groove or a plurality of grooves (also can be referred to as vertical channels and/or vertical grooves) disposed perpendicular to a length of microchannel component 200. FIG. 4, for example, shows a side surface 400 (e.g., side S1 in the x-z plane) with a plurality of grooves (e.g., groove VG1, VG2, . . .VGn) formed in or on side S1. The n grooves (e.g., groove VG1, VG2, . . .VGn) may be linear or lateral grooves that extend linearly over a distance equal to the thickness T of microchannel component 200 in the z direction perpendicular to the long length (length CL) of side S1.

In some implementations, the n grooves (e.g., groove VG1, VG2, . . .VGn) may be non-linear grooves that extend over at least a portion of the thickness T of microchannel component 200 in the z direction perpendicular to the long length (length CL) of side S1. In some implementations, the n grooves (e.g., groove VG1, VG2, . . .VGn) may extend over only a portion of the length CL of the side. In some implementations, the grooves shown in FIG. 4 may be irregularly spaced. In some implementations, the grooves shown in FIG. 4 may be irregularly shaped.

In some implementations, the n grooves (e.g., groove VG1, VG2, . . .VGn) may be grooves that extend over less than the thickness T of microchannel component 200 in the z direction perpendicular to the long length (length CL) of side S1. In some implementations, the n grooves (e.g., groove VG1, VG2, . . .VGn) may be grooves that extend over only a portion of the thickness T of microchannel component 200 in the z direction perpendicular to the long length (length CL) of side S1. In some implementations, the n grooves (e.g., groove VG1, VG2, . . .VGn) may be non-linear grooves that extend over at least a portion of the thickness T of microchannel component 200 in the z direction perpendicular to the long length (length CL) of side S1.

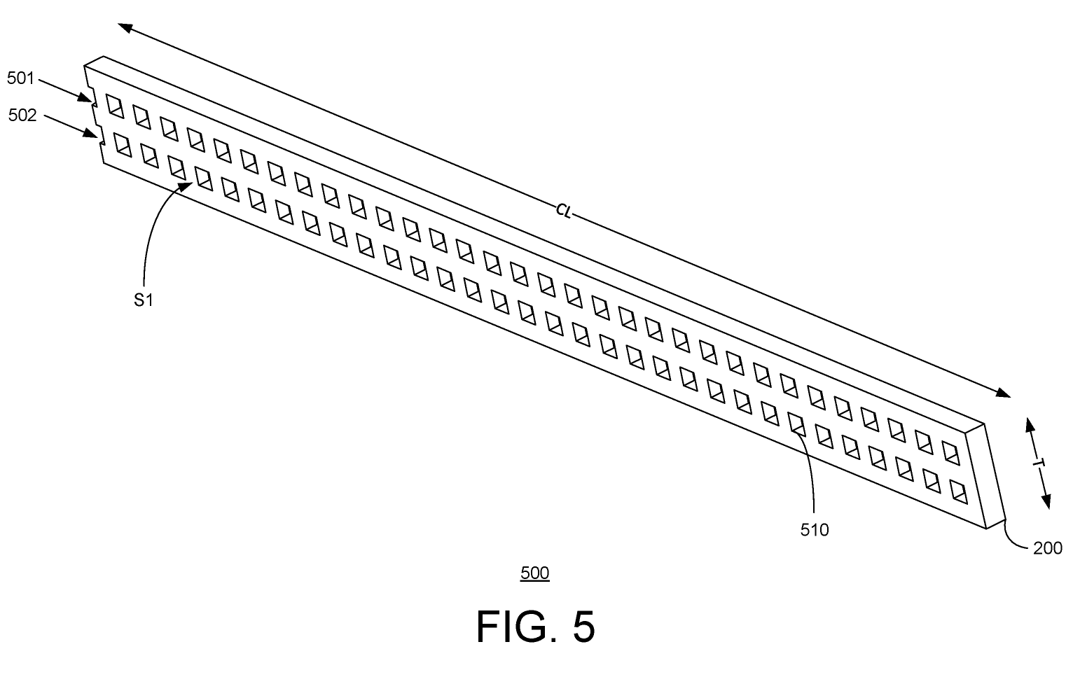

In other example implementations, the mold-lock components disposed on the surface of the microchannel component include a plurality of holes (e.g., hole 510). In some implementations, the holes can be referred to as recesses. FIG. 5, for example, shows a side surface 500 with a plurality of holes (e.g., hole 510) disposed in one or more rows (e.g., row 501, row 502) across a length of microchannel component 200.

In some implementations, the plurality of holes shown in FIG. 5 may be irregularly spaced. In some implementations, the plurality of holes shown in FIG. 5 may be irregularly shaped. In some implementations, the plurality of holes may be included in only a portion of the side (e.g., over only a portion of the thickness T and/or the length CL).

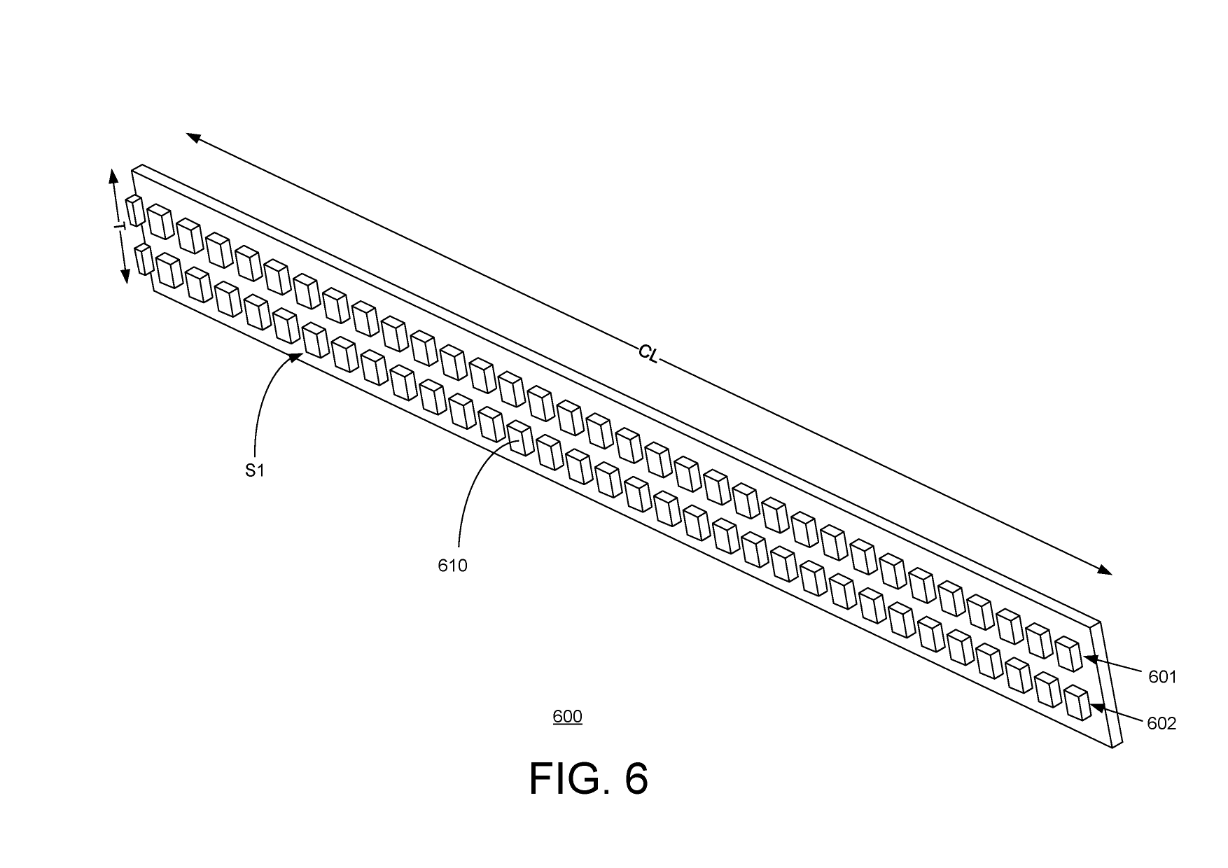

In other example implementations, the mold-lock components disposed on the surface of the microchannel component include a plurality of protrusions (e.g., protrusion 610). A protrusion 610 may, for example, be a protrusion extending perpendicular to the surface. In example implementations, protrusion 610 may have a square, a rectangular, a circular, or other shape cross-section. FIG. 6, for example, shows a side surface 600 with a plurality of protrusions (e.g., protrusion 610) disposed along one or more rows (e.g., row 601, row 602) across a length of microchannel component 200.

In some implementations, the plurality of protrusions shown in FIG. 5 may be irregularly spaced. In some implementations, the plurality of protrusions shown in FIG. 5 may be irregularly shaped. In some implementations, the plurality of protrusions may be included in only a portion of the side (e.g., over only a portion of the thickness T and/or the length CL).

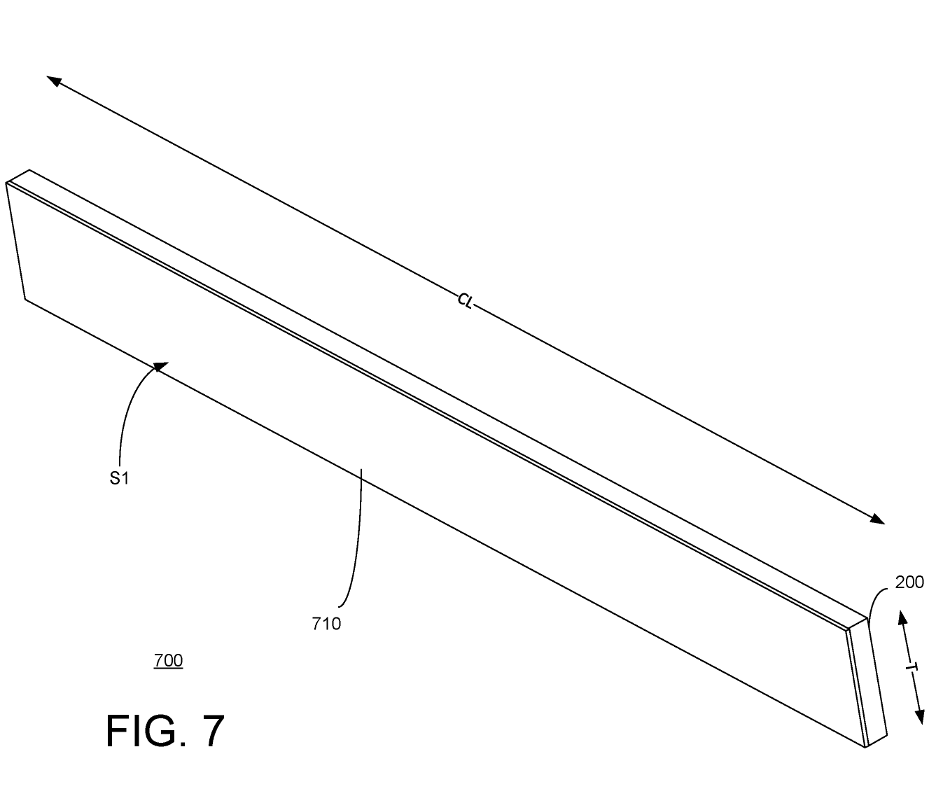

In some example implementations, an adhesive layer may be disposed on the smooth sides (e.g., side S1 and S2) of microchannel component 200 to hold microchannel component 200 in place in mold body 105. FIG. 7, like FIGS. 3 to 6, shows only a side surface (e.g., side S1) of microchannel component 200.

Further, FIG. 7 shows, for example, a side surface 700 with an adhesive layer 710 disposed on a side surface (e.g., side S1) of microchannel component 200. Adhesive layer 710 may, for example, be an epoxy, which may or may not be the same epoxy (e.g., EMC) used to make mold body 105. In example implementations, adhesive layer 710 may be an epoxy that is softer (or less stiff) than the epoxy (e.g., EMC) used to make mold body 105. Adhesive layer 710 may help bind side S1 of microchannel component 200 in the mold body 105.

In some example implementations, a top surface of microchannel component 200 may be prepared or conditioned to provide additional surface area that can be gripped by the epoxy (mold body) may be disposed the smooth sides (e.g., side S1 and S2) of microchannel component 200 to hold microchannel component 200 in place in mold body 105. FIG. 7, like FIGS. 3 to 6, shows only a surface portion (e.g., side S1) of microchannel component 200. Further, FIG. 7 shows, for example, an adhesive layer 710 disposed on a side surface (e.g., side S1) of microchannel component 200. Adhesive layer 710 may, for example, be an epoxy, which may or may not be the same epoxy (e.g., EMC) used to make mold body 105. Adhesive layer 710 may help bind side S1 of microchannel component 200 within the mold body 105.

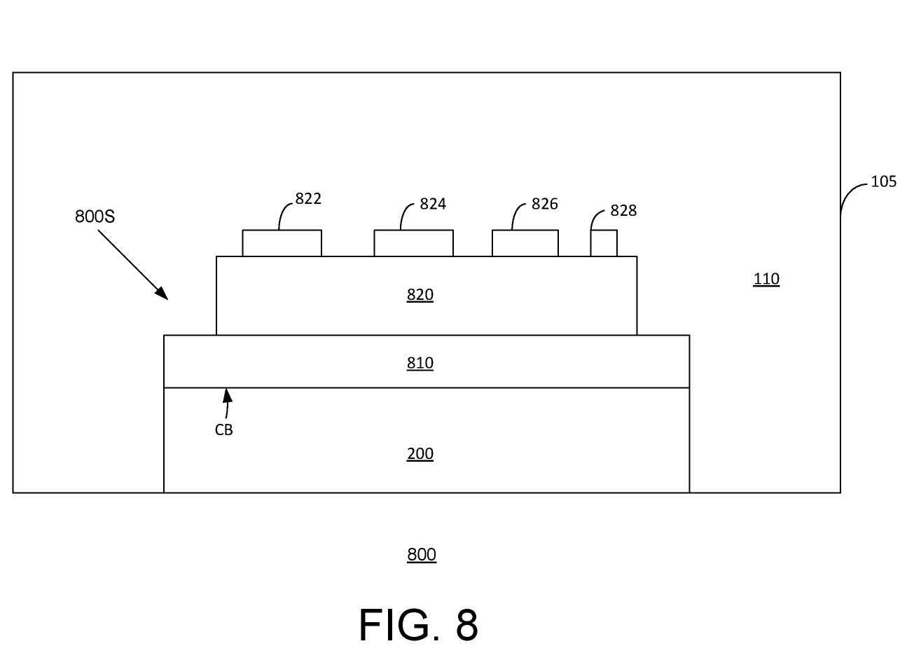

In some example implementation, to minimize the risk of delamination in the semiconductor device package, the microchannel component may be physically or mechanically integrated with the device stacks (i.e., substrate and semiconductor die) that are encapsulated in the package. FIG. 8 shows, in a cross - sectional view, an example assembly in which microchannel component 200 is physically or mechanically integrated with a device stack (e.g., device stack 800S) encapsulated in mold body 105 of a semiconductor device package 800. As shown in FIG. 8, device stack 800S in addition to microchannel component 200 includes an insulating component 810, a metal layer 820, and various semiconductor device dies (or circuit components) (e.g., die 822, die 824, die 826, and die 828).

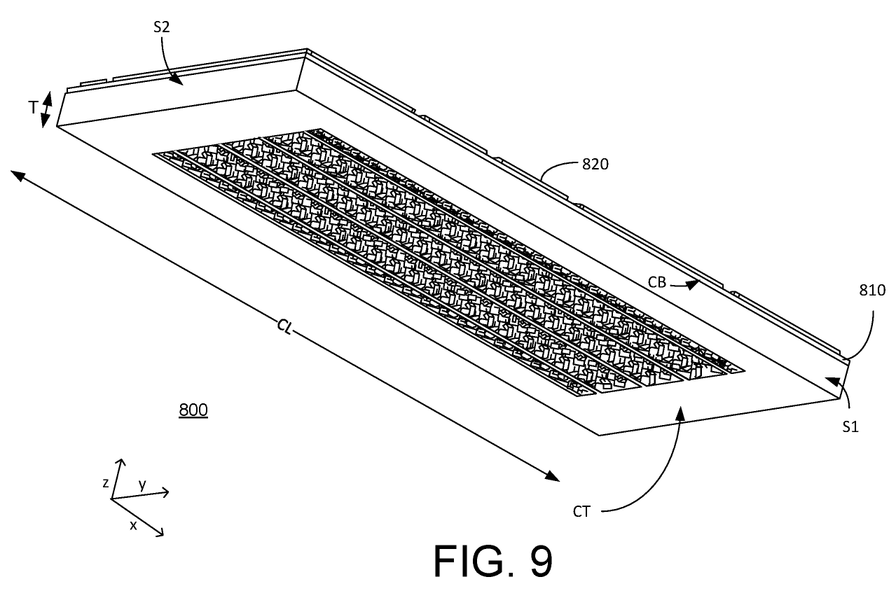

In device stack 800S, as shown in FIG. 9, a bottom surface (e.g., bottom surface CB, FIG. 2) of microchannel component 200 is attached (bonded) to a bottom surface of an insulating component 810. Insulating component 810 may be a thermally conductive but electrically insulating component such as an insulating component. A metal layer 820 (e.g., a copper layer) is disposed on a top surface of an insulating component. Metal layer 820 may be bonded to, or sintered to, a top surface of the insulating component. Further, semiconductor components or dies (e.g., die 822, die 824, die 826, and die 828) may be disposed on die attach pads (DAPs)(not shown) formed on metal layer 820. As shown in FIG. 8, the assembly may be encapsulated in a mold body 105 by an epoxy (e.g., an EMC 110).

FIG. 9 shows a perspective view (like FIG. 2) of an example microchannel component 200 attached (bonded) to insulating component 810. As shown in FIG. 9, insulating component 810 is disposed on the bottom surface (e.g., surface CB) of microchannel component 200. Further, a metal layer 820 is disposed on insulating component 810. Metal layer 820 may, for example, be made of copper, or another metal or a metal alloy.

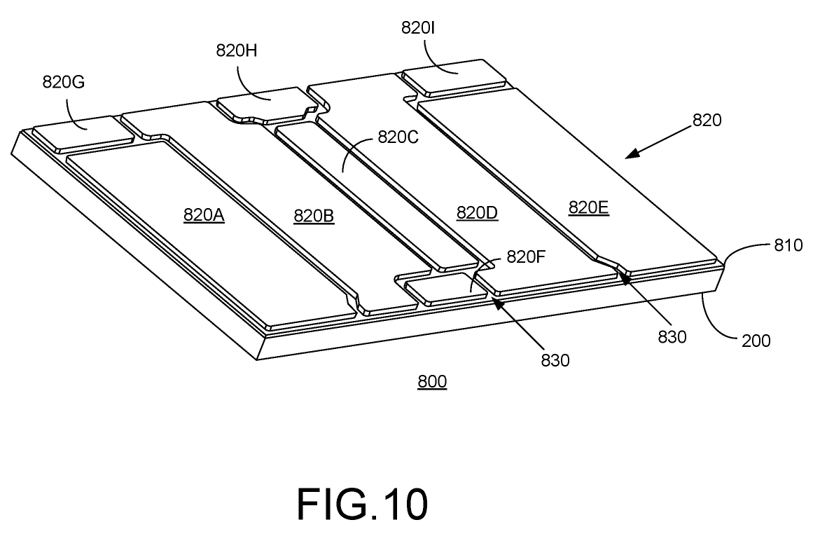

In example implementations, metal layer 820 may be patterned to include several areas or pads (islands) that are electrically isolated from each other by inter-pad grooves etched or cut through metal layer 820. FIG. 10 shows a plan view of metal layer 820 that is patterned to include multiple pads or islands (e.g., pad 820A, pad 820B, pad 820C, pad 820D, pad 820E, pad 820F, pad 820G, pad 820H, and pad 820I, etc.) that are isolated from each other. These pads or islands may be electrically isolated from each other by inter-pad grooves (e.g., inter-pad groove 830). The inter-pad grooves may extend from a top of metal layer 820 through a thickness of the metal layer to the underlying side of the insulating component 810.

In example implementations, the multiple pads (e.g., pad 820A, pad 820B, pad 820C, pad 820D, pad 820E, pad 820F, pad 820G, pad 820H, and pad 820I, etc.) may be configured to receive respective circuit elements (e.g., semiconductor die, discrete devices, terminals, contacts, I/O devices, etc.) that may be included in a device package (e.g., semiconductor device package 100, FIG. 1B). In an example implementations, the circuit elements may include a low-side switch and a high-side switch. The low-side switch elements may be disposed, for example, on pad 820B and the high-side switch elements may be disposed on pad 820D in metal layer 820.

In example implementations, the various elements or layers of device stack 800S (e.g., microchannel component 200, insulating component 810, and metal layer 820, FIG. 8) that are encapsulated in a semiconductor device package (e.g., semiconductor device package 800, FIG. 8, semiconductor device package 100, FIG. 1B) may be mechanically or physically held together by a coupling mechanism (e.g., a screw-and-nut arrangement). The coupling mechanism (e.g., screw-and-nut arrangement) to hold together the various elements or layers of device stack 800S can avoid the risk of delamination after the stack is encapsulated in an epoxy package (e.g., semiconductor device package 100, FIG. 1B). In some example implementations, a screw or bolt may be introduced, for example, at a top of the stack through a hole in metal layer 820 and extend through insulating component 810 into microchannel component 200. In some other example implementations, the screw or bolt may be introduced, for example, at a bottom of the stack through a hole in microchannel component 200 and extend through insulating component 810 into metal layer 820.

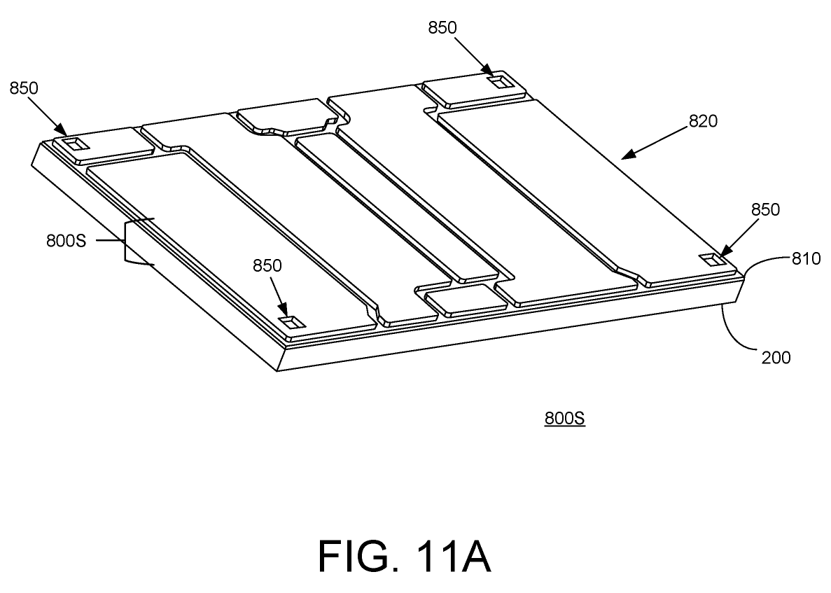

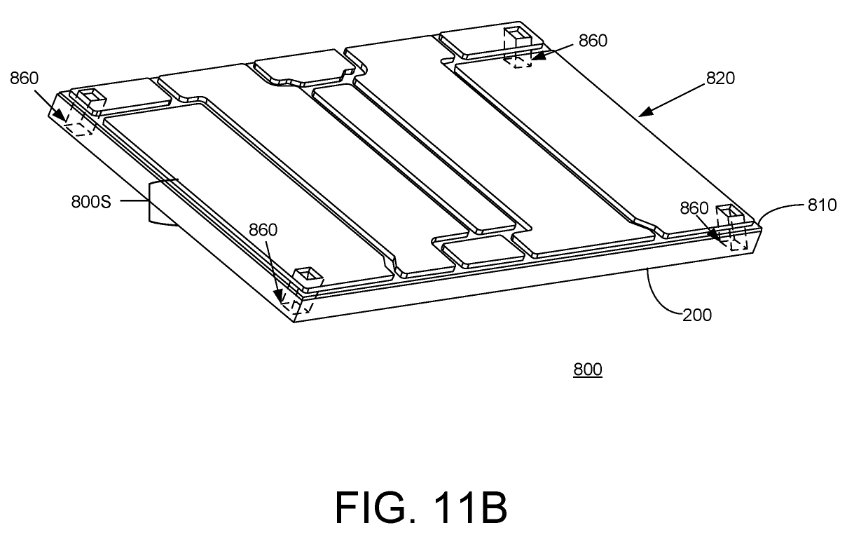

FIG. 11A shows, for example, device stack 800S with four holes (e.g., a hole 850) in metal layer 820 at the four corners at top of the device stack 800S. A screw or bolt (not shown) may be introduced through hole 850 to hold together the various elements or layers of device stack 800S.

FIG. 11B shows, for example, device stack 800S with four holes (e.g., hole 860) in microchannel component 200 at the four corners at a bottom of the device stack 800S. A screw or bolt (not shown) may be introduced through hole 860 to hold the various elements or layers of device stack 800S together.

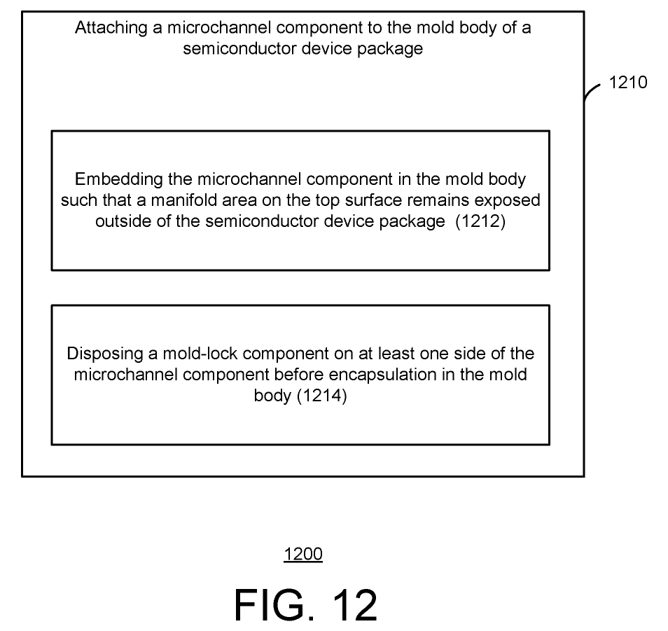

FIG. 12 shows an example method 1200 of using a microchannel component to dissipate heat generated in a semiconductor device package. The semiconductor device package may include at least one semiconductor device encapsulated in mold body made of an epoxy material.

Method 1200 includes attaching a microchannel component to the mold body of a semiconductor device package (1210). The mold body may be made of a molding material such as an epoxy material. The microchannel component includes a manifold area on a top surface. The manifold area has inlet openings and exhaust vents of a plurality of microchannels that extend from one side of the microchannel component to an opposing second side of the microchannel component. Attaching the microchannel component to the mold body (1210) includes embedding the microchannel component in the mold body such that the manifold area on the top surface remains exposed outside of the semiconductor device package (1212). Attaching the microchannel component to the mold body 1210 further includes disposing a mold-lock component on at least one side of the microchannel component before encapsulation in the mold body (1214). The mold-lock component may be configured to be utilized by the encapsulating mold body to hold the microchannel component in place and avoid a risk of delamination in the semiconductor device package.

In some example implementations, disposing a mold-lock component on at least one side of the microchannel component may include disposing a groove on a surface of the at least one side of the microchannel component. The groove may be a linear groove extending along a length of the one side.

In some example implementations, disposing a mold-lock component on at least one side of the microchannel component may include disposing a plurality of grooves on a surface of the at least one side of the microchannel component. The plurality of grooves may be linear grooves extending perpendicular to a length of the one side.

In some example implementations, disposing a mold-lock component on at least one side of the microchannel component may include disposing a plurality of holes on the at least one side of the microchannel component. The plurality of holes may be disposed in one or more rows across a length of the at least one side of the microchannel component.

In some example implementations, disposing a mold-lock component on at least one side of the microchannel component may include disposing a plurality of protrusions on the at least one side of the microchannel component. A protrusion may, for example, be a protrusion extending perpendicular to the surface. In example implementations, the protrusion may have a square, a rectangular, a circular, or other shape cross-section. The plurality of protrusions may be disposed in one or more rows across at least one side of the microchannel component.

In some example implementations, disposing a mold-lock component on at least one side of the microchannel component may include disposing an adhesive layer on the at least one side of the microchannel component. The adhesive layer may be an epoxy that is softer (or less stiff) than the epoxy (e.g., EMC) used to make the mold body (e.g., mold body 105).

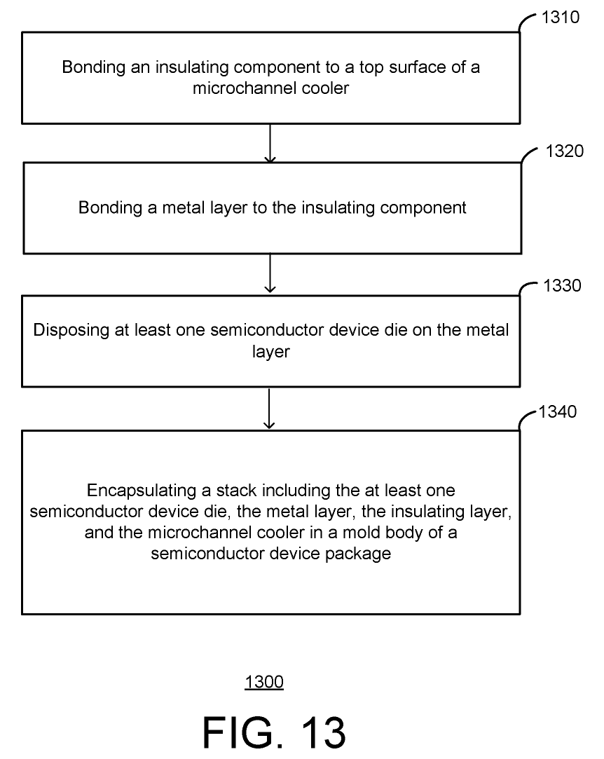

FIG. 13 shows an example method 1300 of using a microchannel component to dissipate heat from a semiconductor device package. The semiconductor device package may include at least one semiconductor device die encapsulated in mold body made of an epoxy material. The method involves mechanically or physically integrating the microchannel component with a device stack that is encapsulated in the semiconductor device package.

Method 1300 includes bonding an insulating component (e.g., ceramic plate) to a top surface of a microchannel component (1310). A bottom surface of the microchannel component may have a manifold area including input openings and exhaust vents of a plurality of microchannels that extend from the manifold area through a thickness of the microchannel component.

Method 1300 further includes bonding a metal layer (e.g., conductive layer) to the insulating component (1320), disposing at least one semiconductor device die or other circuit components on the metal layer (1330), and encapsulating a stack including the at least one semiconductor device die, the metal layer, the ceramic layer, and the microchannel component in a mold body of a semiconductor device package (1340). In some implementations, the microchannel component can be positioned in the mold body such that a manifold area on the bottom surface of the microchannel component remains exposed outside of the semiconductor device package.

In example implementations, method 1300 may further include mechanically or physically holding the various elements or layers of the device stack (e.g., device stack 800S, FIG. 8) that is encapsulated in the semiconductor device package by a screw-and-nut (or bolt-and-nut) arrangement. In some example implementations, a screw or bolt may be introduced, for example, at a top of the stack through a hole in the metal layer 820 and extend through a ceramic layer into the microchannel component. In some other example implementations, the screw or bolt may be introduced, for example, at a bottom of the stack through a hole in the bottom of microchannel component and extend through the ceramic layer into the metal layer.

In example implementations, method 1300 may further include (as in method 1200 described above, FIG. 12) disposing a mold-lock component on at least one side of the microchannel component before encapsulation in the epoxy material. The mold-lock component may be configured to be utilized by the encapsulating epoxy material to hold the microchannel component in place and avoid a risk of delamination in the semiconductor device package.

Referring back to, for example, FIGS. 1A and 1B, one or more semiconductor die can be coupled to one more DBM substrates. In some implementations, the direct bonded metal (DBM) substrate (e.g., direct bonded copper (DBC)) can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate (e.g., a DBM with copper metal layers). In some implementations, such as in DBC substrate implementations, the first metal layer and/or the second metal layer is a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

In some implementations, one or more semiconductor dies (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a Schottky barrier diode, and/or so forth. In some implementations, one or more semiconductor die can be (e.g., can be a portion of), or can include a circuit component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wire bonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a spacer material can be an epoxy, a silicone adhesive, a conductive material, a non-conductive material, an organic material, a semiconductor material, a metal alloy, a metal foam, a phase change material, etc.

In some implementations, a module (e.g., a package including a semiconductor device) can be included in another module. The module can be referred to as a package. For example, one or more modules can be one or more sub modules included within another module. In other words, a first module can be included as a sub module within a second module.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to, may not be used throughout the detailed description, elements that are shown as being directly on, directly connected or directly coupled can be referred to as such. The claims of the application may be amended to recite exemplary relationships described in the specification or shown in the figures.

In some implementations, soldering can be, or can include a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

As used in this specification, a singular form may, unless definitely indicating a particular form in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A package, comprising:
a mold body made of a molding material, the mold body encapsulating at least a semiconductor die; and
a microchannel component embedded the mold body with a manifold area of a top surface of the microchannel component being exposed to an ambience of the mold body, the manifold area including openings to a plurality of microchannels that extend through a thickness of the microchannel component to a back surface in thermal contact with the semiconductor die.

2. The package of claim 1, wherein the microchannel component has a side surface corresponding to the thickness of the microchannel component, and wherein a mold-lock component is disposed on the side surface.

3. The package of claim 2, wherein the mold-lock component includes at least one groove extending along a length of the side surface.

4. The package of claim 2, wherein the mold-lock component includes a plurality of grooves extending perpendicular to a length of the side surface.

5. The package of claim 2, wherein the mold-lock component includes a plurality of holes disposed in at least a row along a length of the side surface.

6. The package of claim 2, wherein the mold-lock component includes a plurality of protrusions disposed in at least a row along a length of the side surface.

7. The package of claim 6, wherein the plurality of protrusions include at least a protrusion extending perpendicular to the side surface.

8. The package of claim 6, wherein the plurality of protrusions include a protrusion having a square, a rectangular, or a circular shape cross-section.

9. The package of claim 2, wherein the mold-lock component includes an adhesive layer disposed on the side surface, the adhesive layer being made of a material that is a same as the molding material of the mold body.

10. The package of claim 2, wherein the mold-lock component includes an adhesive layer disposed on the side surface, the adhesive layer being made of material that has a stiffness that is less than a stiffness of the molding material of the mold body.

11. The package of claim 2, wherein the microchannel component is made of a metal or a metal alloy.

12. The package of claim 2, wherein the microchannel component has a three-dimensional rectangular shape with a length, a width and a thickness.

13. A package, comprising:
a mold body made of a molding material encapsulating a stack, the stack including:
a microchannel component having a surface with a manifold area therein, the manifold area including openings to a plurality of microchannels that extend from the manifold area through a thickness of the microchannel component;
an insulating component bonded to the microchannel component on a side of the microchannel component opposite the surface with the manifold area;
a metal layer disposed on the insulating component; and
at least one semiconductor device die disposed on the metal layer.

14. The package of claim 13, wherein the metal layer is bonded to the insulating component.

15. The package of claim 13, wherein the metal layer disposed on the insulating component is patterned to form a plurality of isolated pads that are separated from each other by a groove extending through a thickness of the metal layer, and wherein a semiconductor device die is disposed on a respective isolated pad.

16. The package of claim 13, wherein the metal layer on the insulating component is made of copper or a metal alloy.

17. The package of claim 13, wherein the stack is physically held together by a screw-and-nut arrangement utilizing at least a hole provided in a corner of the stack.

18. A method comprising:
bonding an insulating component to a bottom surface of a microchannel component, a top surface of the microchannel component having a manifold area including openings to a plurality of microchannels that extend from the manifold area through a thickness of the microchannel component;
bonding a metal layer to the insulating component;
disposing at least one semiconductor device die on the metal layer; and
encapsulating a stack including the at least one semiconductor device die, the metal layer, the insulating component and the microchannel component in a molding material forming a mold body of a semiconductor device package such that the manifold area on the top surface of the microchannel component remains exposed outside of the semiconductor device package.

19. The method of claim 18, wherein bonding a metal layer to the insulating component further includes patterning the metal layer to form a plurality of isolated pads on the insulating component and wherein disposing at least one semiconductor device die on the metal layer includes disposing the at least one semiconductor device die on one of the plurality of isolated pads.

20. The method of claim 18, further comprising:
physically holding the stack together using a screw-and-nut arrangement utilizing at least a hole provided in a corner of the stack.

21. The method of claim 18, further comprising:
disposing a mold-lock component on at least one side surface of the microchannel component before encapsulation in the molding material.
